(19) United States
(12) Patent Application Publication
(10) Pub. No.: US 2010/0155575 A1
(43) Pub. Date: Jun. 24, 2010

(54) ARRANGEMENT AND METHOD IN AN ELECTRONIC DEVICE FOR DETECTING A USER INPUT TO A KEY

(75) Inventor: Magnus Lundin, Bromma (SE)

Correspondence Address: HARRITY & HARRITY, LLP, 11350 RANDOM HILLS ROAD, SUITE 600, FAIRFAX, VA, 22030, US

(73) Assignee: Sony Ericsson Mobile Communications AB, Lund (SE)

(21) Appl. No.: 12/339,976

(22) Filed: Dec. 19, 2008

(51) Int. Cl. H01J 40/14; H01L 31/042; H04B 1/38

(52) U.S. Cl. 250/206; 136/244; 455/572

(57) ABSTRACT

A method in an electronic device for detecting a user input to a key of the electronic device associated with a solar cell that may include an input and an output is provided. The key may be transparent and admit input electromagnetic radiation to the solar cell. A change of input radiation into the solar cell may result in a corresponding change of an output signal of the solar cell. The method may include the step of detecting a change of the output signal corresponding to a change in input radiation as a result of light being blocked from being incident on the key (e.g., shadowed), and the step of indicating an input (i.e., activation) of the key associated with the solar cell with the detected output signal change.

### TECHNICAL FIELD

The present invention generally relates to an arrangement and a method in an electronic device and, more particularly, to detecting a user input to a key of the electronic device.

### BACKGROUND

The use of electronic devices is commonplace today. Many popular electronic devices are wireless. Examples of such wireless devices include wireless phones, smart phones, cameras, laptops, and music players, such as mp3-players, and video devices. Furthermore, a wireless device of today may include one of more these functionalities. Many electronic devices—especially wireless devices—are powered by a battery. If the battery becomes depleted, all features are rendered useless, preventing even basic or necessary functions, such as the ability for a wireless phone to make emergency calls, e.g., a 911-call. For safety reasons, it is extremely important that a wireless device is operational anytime, anywhere. Many solutions are proposed to prolong the battery life for longer standby time and active time (e.g., talk time). Problematically, once the battery runs out of energy, the wireless device is not operational.

The batteries of wireless device may be high-density batteries or rapid-charging batteries, which eventually exhaust and thereby require recharging. The need for recurring recharging of the batteries forces the user of the wireless device to keep a charging device at hand every time the batteries run low. This may be cumbersome and impractical, especially in less-developed areas of the world, where the power grid may not be accessible and/reliable at regular, predictable intervals. Furthermore, the rechargeable batteries age in the sense that the ability to retain a charge (i.e., battery life) gradually decreases.

Substitutes and/or complements to using rechargeable batteries as a power source of an electronic device are alternative power sources, such as solar cells and photovoltaic arrays, which are capable of converting electromagentic radiation of, for example, sunlight directly into electricity, where the plentiful energy from the sun is converted into electricity. This is particularly useful for electronic devices which are otherwise operably limited to the electric charge of the battery.

A wireless electronic device with solar cells is described, for example, by U.S. Pat. No. 5,898,932, entitled “Portable Cellular Phone with Integral Panel.” The patent disclosure presents a cellular phone having a rear face provided with solar cells, which are used to recharge the batteries of the cell phone.

Another relevant disclosure is U.S. Pat. No. 6,847,834, entitled “Mobile Terminal with a Solar Cell,” which describes a wireless electronic device with a flip cover that has solar cells attached to the outer surface of the flip cover.

The above solutions have the disadvantage of occupying relatively large surface areas of the electronic device for the solar cells, areas that cannot be used for anything else. As the electronic devices become increasingly smaller and concurrently are equipped with more functionalities, the size requirements of the solar cells become more rigid. For example, both the backside and front side of the electronic device are required to serve as user interface (UI) to enable the providing/put into practice of all the functions of the device. Examples of such functions include wireless telephony, camera, video recorder, music player, keyboard functionality, calendar display, global positioning system (GPS) with map, Internet browser, chat window, e-mail client, etc.

### SUMMARY OF THE INVENTION

Embodiments of the invention provide a mechanism for efficiently powering electronic devices.

Embodiments of the invention implemented in an electronic device may use a solar cell that may serve as both an input element and a power source.

According to a first aspect of the present invention, a method in an electronic device may detect a user input to a key of the electronic device. The key may be associated with a solar cell. The solar cell may include an input and an output. A change of input radiation into the solar cell may result in a corresponding change of an output signal of the solar cell. The key may be transparent and adapted to admit input radiation to the solar cell. The method may include the step of detecting a change of the output signal corresponding to a change in input radiation as a result of the key being screened off, and a further step of indicating an input of the key associated with the solar cell with the detected output signal change.

According to a second aspect of the invention an electronic device may include a key and a solar cell that includes an input and an output. A change of input radiation into the solar cell may result in a corresponding change of an output signal of the solar cell. The key may be transparent and adapted to admit input radiation to the solar cell. The device may be characterized in that the key may be associated with the solar cell. The electronic device may include a cell monitoring unit adapted to detect a change of the output signal corresponding to a change in input radiation as a result of the key being screened off. The cell monitoring unit may be adapted to indicate an input of the key associated with the solar cell with the detected output signal change.

An advantage of the present device implemented in embodiments of the present invention may allow electronic devices to be produced smaller, thinner, and/or lighter since small solar cells are used as an equivalent to touch buttons. Buttons often require a fair amount of dedicated space, and by combining these two functions, the available surface area of the electronic device may be used more efficiently as the solar cells are used for both input functions, such as user input mechanisms and sources of power.

### BRIEF DESCRIPTION OF THE DRAWINGS

The present invention will now be described more in detail in relation to the enclosed drawings in which:

FIG. 1 is a front view and a side view of embodiments of an electronic device;

FIG. 2 illustrates a schematic view of embodiments of a solar cell;

FIG. 3 illustrates embodiments of a detail view of an electronic device;

FIG. 4 illustrates embodiments of a detail view of an electronic device;

FIG. 5 is a flow chart illustrating embodiments of method steps; and

FIG. 6 is a block diagram illustrating embodiments of an electronic device.

### DETAILED DESCRIPTION

The invention may include an electronic device having a solar cell, which may be practiced in the embodiments further described below.

The invention is directed to several technology areas, such as battery and charging and man-machine-interface (MMI) and user interface (UI) features. This invention describes the use of small solar cells as corresponding to touch buttons. Buttons often require quite some space and by combining these two, the available area is used more efficiently. The invention may be used in a battery-powered electronic device. The present invention may allow electronic devices to have small, thin, and/or light physical dimensions.

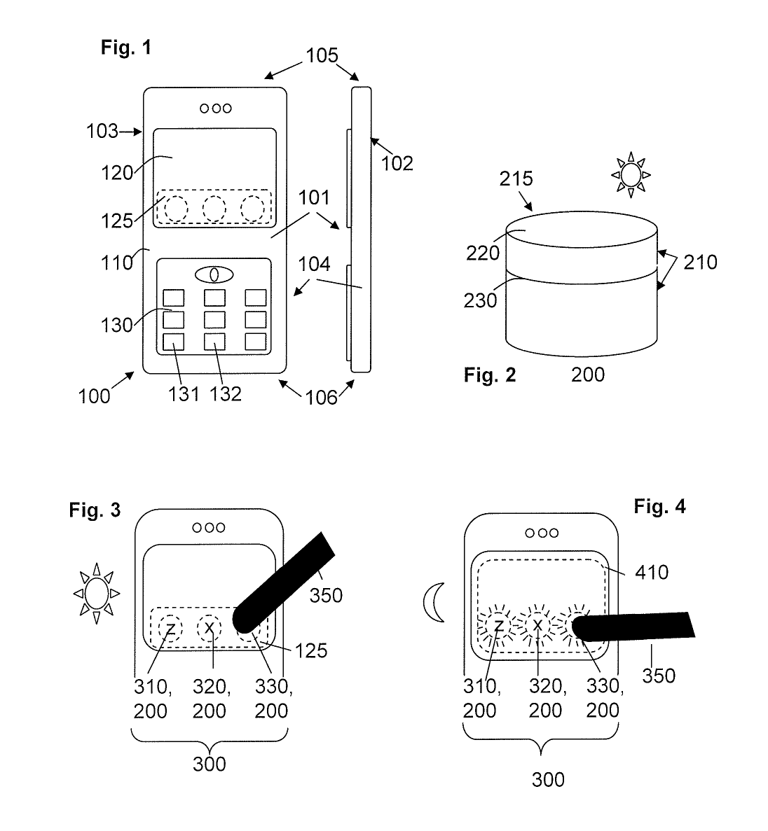

FIG. 1 presents a front and side views of an electronic device 100 for which the invention may be applicable. Examples of such electronic devices include, for example, a wireless phone, a smart phone, a laptop, a remote control, an instrument such as a clock, a music player such as an mp3 player, and/or a digital camera. The invention may also be applicable to any electronic product that includes an input functionality, such as a user interface in the form of buttons, a touch screen, and/or other input mechanisms, and an electric power source, such as a battery. Examples of such electronic products include outside stationary devices that are not hooked up to the power grid such as a warning light device used at construction works on roads, a solar powered garden illumination device, etc.

As depicted in FIG. 1 electronic device 100 may include a front side 101, a back side 102, a first side 103, and a second side 104, a top 105, and/or a bottom 106. Front side 101 may be that portion of electronic device 100 that may be intended to face a user of electronic device 100. Back side 102 may be essentially parallel to front side 101. First side 103 may be, for example, the left side, and second side 104 may be the right side of electronic device 100. Top 105 may be intended to be the upper side of electronic device 100 and bottom 106 may be intended to be the underside of electronic device 100. Of course, other orientations are possible.

Electronic device 100 may include a casing 110 that may encapsulate mobile device 100. Electronic device 100 may include a display 120 and an input interface 130. Input interface 130 may include input elements 131, 132, such as buttons, keys, and/or a keyboard. Electronic device 100 may include a number of input elements 131, 132. The embodiment shown in FIG. 1 includes at least ten input elements but only two input elements 131, 132 are numbered, due to limited space in FIG. 1. Input elements 131, 132 may be located on front 101 and/or back 102 and/or first side 103 and/or second side 104. Input elements 131, 132 will hereafter be referred to as keys 131, 132. According to some embodiments, portions and/or an entirety of input interface 130 may be collocated with display 120 to form an input sensible display 125. Electronic device 100 may include a plurality of components, some or all not shown in FIG. 1, enabling further functionalities, such as wireless telephony, photo shooting, time telling, the sending and receiving of short messages, downloading of pictures, sound and multimedia playing in electronic device 100. Such components may be. For example, a transceiver, a radio communication unit, a microphone, and/or a speaker. This list is not considered to be limiting but only serves as showing a number of examples.

According to some embodiments, electronic device 100 may include a power management system, not depicted in FIG. 1, which has as a primary power source an array of solar cells. The power management system may include a backup power source, such as a rechargeable battery. The solar cells may produce electric voltage and/or current for (mobile) electronic device 100 by converting input, such as sunlight, ambient light, heat, even starlight into output of electricity used to power electronic device 100. The present invention may enable electronic device 100 to operate anytime and anywhere.

The power management system may be configured to control power to and/or from the solar cells; and be further adapted to control power to and/or from the battery supply. According to some embodiments, electronic device 100 is primarily being powered by power provided form the solar cells. When the provided solar cell power is insufficient to supply one or more or any of the components of electronic device 100, electronic device 100 may instead be powered with both solar cell power and battery power provided by the battery. The solar cell array may be connected to supply power to the rechargeable battery. The output electricity of the solar cell array, for example, in the form of voltage, may be converted to higher voltage using, for example, a common boost converter. According to some embodiments, in which the solar cells may not be capable of charging the battery, the solar cells may be capable of empowering some portion of electronic device 100 that does not require high voltage.

Electronic device 100 may also be capable of being attached to an external charger that is capable of providing charger power to the rechargeable battery.

The array of solar cells will now be discussed in detail. The array of solar cells may include a number of small solar cells. FIG. 2 depicts an embodiment of a solar cell 200 that may be part of a solar cell array according to the present invention.

Solar cell 200 may be enclosed in a casing 210. A front part 215 of casing 210 may be configured to face the source of light, for example, the sun. Front part 215 may include a transparent surface 220 covering a film 230. Film 230 may be configured to convert the input of light into an output of electric energy. The electric energy output may be, for example, voltage and/or current.

There are several different types of solar cells that may be applicable to the present solution, such as high efficiency solar cells and/or solar cells made of cadmium telluride (CdTe), copper indium gallium selenide (CuInSe), amorphous silicon, and/or micromorphous silicon. According to some embodiments, solar cell 200 may be represented by an infrared solar cell, configured to harvest heat energy.

According to some embodiments, the size of solar cells 200 of the solar cell array of the present solution may be, for example, “finger tip size”, e.g., corresponding to approximately 1-2 cm² and/or any other surface area. The shape of solar cells 200 of the solar cell array may be, for example, round and/or any other regular or irregular shape.

Solar cells 200 may be located on any surface of the mobile device 100 that is available. That is to say the solar cells 200 of the solar cell array may be located on the front 101, the back 102, the first side 103 and/or the second side 104, the top 105 and/or the bottom 106.

The present invention may include embodiments in which solar cells 200 of the solar cell array may serve as keys 131, 132. According to some embodiments, solar cell 200 may be located in the vicinity of one of keys 131, 132 to which it is associated. Thereby solar cell 200 detects user input to the associated key. Solar cell 200 may be part of display 120 to form input sensitive display 125. The present solution is particularly advantageous as solar cell 200 of the present invention are most space efficient when serving as both the power source and keys 131, 132 of electronic device 100.

FIG. 3 shows a detailed view of embodiments of electronic device 100, which may include a solar cell array 300. Solar cell array 300 may include solar cells 200 and may be part of input sensitive display 125 to enable the equivalent of a touch screen. FIG. 3 depicts an embodiment in which there are three solar cells 200 in solar cell array 300. Solar cells 200 may serve as keys 310, 320, and 330. The number of solar cells 200 constituting solar cell array 300 may be large, and is only limited by firstly the size of individual ones of solar cell 200 and secondly by the size of the available area of electronic device 100 whereat the keys 310, 320, 330 may be disposed.

According to some embodiments, solar cell 200 may include a picture such as a permanent transparent print on top of transparent surface 220, which visualizes keys 310, 320, 330. Another way of visualizing keys 310, 320, 330 on top of solar cell 200, may be to cover solar cell 200 with a transparent display layer depicting keys 310, 320, 330 to which solar cell 200 is associated.

The following section describes the operation of solar cell 200 as being associated to a particular one or more of keys 310, 320, 330, according to some embodiments, in which solar cell 200 converts light input into voltage output. FIG. 3 depicts a normal light condition, such as during daytime, when solar cells 200 of solar array 300 may produce a first output level, here denoted O₁, due to incident ambient light. Any of keys 310, 320, 330, for example, key 330, may be “pressed,” thereby obscuring the sunlight from keys 310, 320, 330, for example, using an object 350, such as the finger of a user. As depicted in FIG. 3, key 330 is “pressed” or activated by being screened out by object 350. Then solar cell 200 corresponding to “pressed” key 330 may produce a second output level, here denoted O₂. According to some embodiments, second output level O₂ of solar cell 200, associated with activated key 330, may be measurably lower than first output level O₁. The output level of solar cells 200 associated with non-activated ones of keys 310, 320 may register high. In order for electronic device 100 to be configured to detect user input of individual ones and/or combinations of keys 310, 320, 330, the output of individual ones of solar cells 200 corresponding to keys 310, 320, 330 may be monitored. Each solar cell 200 that makes up an individual one of keys 310, 320, 330 may be monitored separately, for instance. Several ones of solar cells 200 may be commonly associated with a single one of keys 310, 320, 330.

FIG. 4 presents embodiments of electronic device 100 applicable for limited-light environments, during evening hours and/or indoors. Electronic device 100 may include an illumination unit 410. Illumination unit 410 may be disposed in the vicinity of solar cells 200 associated with keys 310, 320, 330. Illumination unit 410 may be adapted to illuminate solar cells 200. According to some embodiments, there may be several illumination units 410, for example, one illumination unit 410 per solar cell 200. Other embodiments may include one illumination unit 410 per key 310, 320, 330. Illumination unit 410 may be configured to provide light of a frequency (and/or wavelength) range in which solar cell 200 is sensitive. Depending on the type of solar cell 200 being used, the sensitivity may be different for different wavelengths of light. Illumination unit 410 may be adapted to be activated when a change in output is detected on several, for example, all, solar cells 200 at the same time (i.e., concurrently), since this may be an indication of a change of environment, such as when electronic device 100 is transported from a bright environment to a dark environment.

Solar cell 200 associated with keys 310, 320, 330 may produce a third output level, here denoted as O₃, when being illuminated by illumination unit 410. As depicted in FIG. 4 electronic device 100 may be adapted to detect the “pressing” of key 330 when the output, of solar cell 200 associated to key 330, increases. This is due to the fact that more light will be reflected, by object 350, back to solar cell 200 associated with key 330, since the object is illuminated by illumination unit 410 when object 350 is “pressing” key 330. Then solar cell 200, associated with activated key 330, will produce a fourth output level, here denoted as O₄. According to these embodiments, fourth output level O₄ may be higher than that of third output level O₃.

According to some embodiments, solar cell 200 associated with keys 310, 320, 330 may include infrared solar cells. Infrared solar cells may be adapted to detect heat and may thus be capable of detecting the heat given off from object 350, when object 350 is represented by something warm, such as the finger of the user of electronic device 100. According to one embodiment, the detected output level when key 310, 320, 330 is “pressed” may be higher, due to the heat from object 350, than the detected output level of “non-pressed” ones of keys 310, 320, 330, when the temperature of the surroundings of the environment of electronic device 100 is lower than the temperature of object 350. Then electronic device 100 may be adapted to use third output level O₃ to indicate an “non-pressed” (i.e., non-activated) keys 310, 320, 330 and fourth output level O₄ to indicate a “pressed” one of keys 310, 320, 330. This embodiment may be applicable in any light condition and may obliterate the need for operation of illumination unit 410.

When a change in output level of solar cell 200 associated with keys 310, 320, 330 is detected, electronic device 100 may compare the detected output change to a threshold delta (Δ). This is performed to lower the sensitivity of the system such that a user input is not detected as soon as the light conditions around electronic device 100 differs the least amount. According to some embodiments mentioned above, there may be several thresholds used depending on, for example, the light conditions, the temperature, and/or other factors. The thresholds may be relative or absolute.

When a change in output of solar cell 200 associated with particular ones of keys 310, 320, 330 is detected, electronic device 100 indicates an input of keys 310, 320, 330 associated with solar cell 200 with the detected output change Δ. According to the embodiments depicted in FIGS. 3 and 4, when “pressing” key 310 with the figure “z” depicted on top, by screening out the input radiation, here in the shape of light, to solar cell 200 associated with key 310, an output change Δ of solar cell 200 associated with key 310 may be detected. The detected output change Δ of solar cell 200 may correspond to the change in input radiation of solar cell 200. Then a user input will be indicated to the “z” key 310 which is associated with solar cell 200 with the detected output change Δ. When a user input is detected, as described above, the application and/or function corresponding to user input detected keys 131, 132 may be activated. An example: when key 131 corresponding to a “send” command in an email application is “pressed,” the send command will be activated by the email application of electronic device 100.

Embodiments of the present invention may also be applicable to a form of a keyboard, such as a QWERTY-board, by providing at least one of solar cells 200 for each of keys 310, 320, 330 of the keyboard.

According to some embodiments, solar cells 200 may be disposed on any of the sides of electronic device 100, thereby enabling several input sensible displays 125 and input units 130 concurrently.

Embodiments of the present invention may be configured to enable the equivalent of multi-touch functionality. Multi-touch may be provided by a touch sensitive device, such as a touch screen, by detecting multiple touch points. According some embodiments, solar cell array 300 may include several small ones of solar cells 200 associated with keys 310, 320, 330. As each of solar cells 200, the equivalent of multi-touch is enabled by simultaneously detecting input of several ones of solar cells 200, each associated with ones of keys 310, 320, 330.

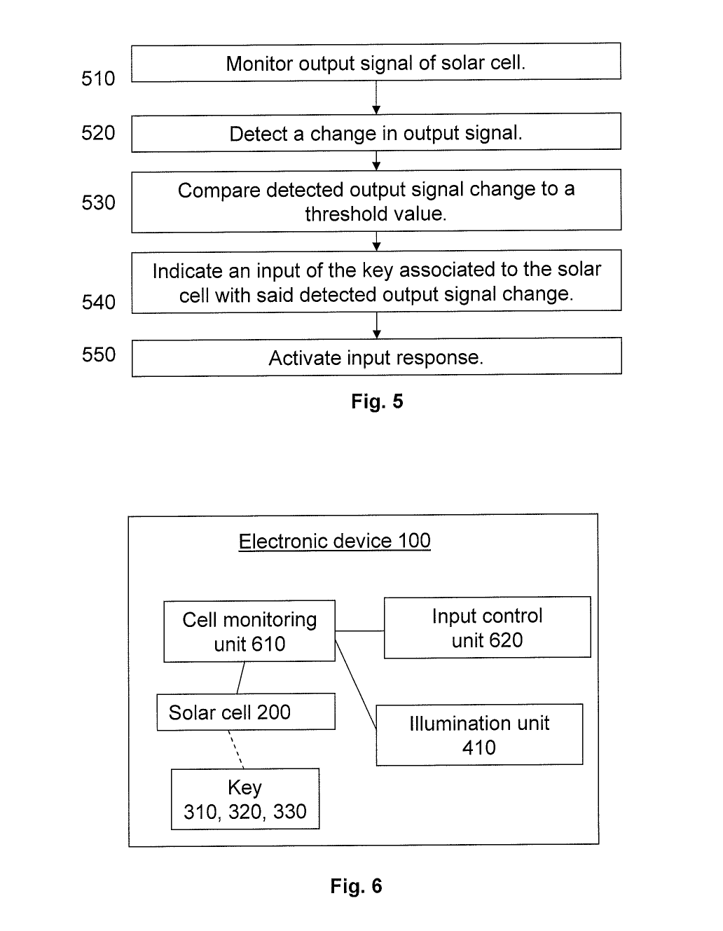

The present invention will now be described in detail with reference to FIG. 5. FIG. 5 presents the steps of a method for detecting a user input to ones of keys 310, 320, 330, performed by electronic device 100. As mentioned above, ones of keys 310, 320, 330 may be associated with particular ones of solar cells 200, and keys 310, 320, 330 may be included in electronic device 100. Solar cells 200 may include an input and an output, wherein a change of input radiation into solar cells 200 may result in a corresponding change Δ of an output signal of solar cells 200. Keys 310, 320, 330 may be transparent and adapted to admit input radiation to solar cells 200. The method may include, for example, the following steps:

Step 510. In this step, the output signal of solar cells 200 may be monitored to enable the next step of detecting a change Δ of the monitored output signal. According to some embodiments, electronic device 100 may include keys 310, 320, 330, with each key 310, 320, 330 respectively being associated to a particular one of solar cells 200. Solar cell 200 being associated to an individual one of keys 310, 320, 330, may be separately monitored.

Step 520. A change Δ of the output signal, corresponding to a change in input radiation, as a result of one or more of keys 310, 320, 330 being shielded from incident light off, may be detected.

Step 530. The detected output signal change Δ may be compared to a threshold value range. When the threshold is attained, the next method step 540 of indicating an input of which of keys 310, 320, 330 corresponds to the detected output signal change Δ may be triggered. According to some embodiments, the threshold value may be represented by a first threshold applicable when the input radiation is high and a second threshold applicable when the input radiation is low.

Step 540. Thereafter, an input of one of keys 310, 320, 330 associated to one of solar cells 200 with the detected output signal change Δ, may be indicated.

Step 550. An input response may be activated, which may be triggered by the indicated key input. The input response may be represented by the playing of a sound and/or the illumination of the activated one(s) of keys 310, 320, 330 with the detected output signal and/or the illumination of all or a select portion of display 120.

To perform the above-described method steps 510-550 in electronic device 100 for detecting a user input to a particular one of keys 310, 320, 330, electronic device 100 may include the following arrangements, as depicted in FIG. 6.

As mentioned above, electronic device 100 may include a predetermined number of solar cells 200. Solar cells 200 may include an input and/or an output. A change of input radiation into solar cells 200 may result in a corresponding change Δ of an output signal of solar cells 200. Solar cell 200s may be an infrared (IR) solar cell. Electronic device 100 may be powered, at least in part, by energy produced by solar cells 200.

Electronic device 100 may include a predetermined number of keys 310, 320, 330 associated with particular ones of solar cells 200. Keys 310, 320, 330 may be transparent and adapted to admit input incident electromagnetic light radiation to solar cells 200. Electronic device 100 may include a plurality of keys 310, 320, 330, each key 310, 320, 330 respectively being associated corresponding ones of solar cells 200.

Electronic device 100 may include a cell monitoring unit 610. Cell monitoring unit 610 may be adapted to detect a change Δ of the output signal corresponding to a change in input radiation as a result of one or more of keys 310, 320, 330 being touched or otherwise obscured. Cell monitoring unit 610 may be adapted to indicate an input of one or more of keys 310, 320, 330 associated with a particular one of solar cells 200 corresponding to the detected output signal change Δ. Cell monitoring unit 610 may be adapted to monitor the output signal of the corresponding one of solar cells 200 to enable the detection of a change Δ of the monitored output signal. Cell monitoring unit 610 may be adapted to separately monitor the output signal of the particular one of solar cells 200 being associated with an individual one of keys 310, 320, 330. According to some embodiments, cell monitoring unit 610 may be adapted to compare the detected output signal change Δ to a threshold value. When the threshold value is attained, cell monitoring unit 610 may be adapted to trigger the indicating of an input from the particular one of keys 310, 320, 330 associated with one of solar cells 200 with the corresponding detected output signal change Δ. According to some embodiments, cell monitoring unit 610 may be adapted to determine when illumination unit 410, described below, is switched on and/or switched off.

Electronic device 100 may include an input control unit 620. Input control unit 620 may be adapted to activate an input response. The activation may be triggered by the indicated key input. According to some embodiments, electronic device 100 may include illumination unit 410 disposed in the vicinity of solar cells 200. Illumination unit 410 may be adapted to illuminate one or more select and/or each of solar cells 200. Illumination unit 410 may be connected to cell monitoring unit 610.

Electronic device 100 may include a wireless device and/or a radio communication device.

The parts or all of the present method and arrangements for detecting a user input to a key can be implemented through one or more processors together with computer program code for performing the functions of the invention. The program code mentioned above may also be provided as a computer program product, for instance in the form of a computer-readable medium storing computer program code of instructions for performing the present method, when being loaded into and/or executed by electronic device 100. One such medium may include, for example, a CD ROM disc. It is, however, feasible with other media, such as a memory stick. The computer program code can be provided as pure program code on a server and downloaded to electronic device 100 remotely, for example, from the Internet and/or another user device.

When using the words “comprise,” “comprising,” “include,” including,” and/or variations thereof, it shall be understood to be non-limiting, in the meaning of “consist at least of.”

The present invention is not limited to the above-described embodiments. Various alternatives, modifications, and/or equivalents may be used. Therefore, the above embodiments should not be taken as limiting the scope of the invention, which is defined by the appending claims.

1-17. (canceled)

18. In an electronic device, a method for detecting a user input of at least one key associated with a solar cell, of the electronic device, having an associated output signal, where a change of input radiation received at the solar cell corresponds to a change in the output signal, the at least one key to transmit input radiation incident upon the at least one key to the solar cell, the method comprising:
detecting the change in the output signal corresponding to the change in the transmitted input radiation when the input radiation is prevented from being received at least one key; and
indicating, based on the detected output signal change, the user input of the at least one key.

19. The method of claim 18, further comprising:
monitoring the output signal of the solar cell to enable the detecting of the change in the output signal.

20. The method of claim 19, where the at least one key comprises a plurality of keys, each of the keys being respectively associated to one solar cell of a plurality of solar cells of the electronic device, and the output signals of each of the associated solar cells is individually monitored.

21. The method of claim 18, further comprising:
comparing the detected output signal change to a threshold value; and
when the threshold value is attained, triggering the indicating the user input of the at least one key.

22. The method of claim 21, where the threshold value comprises a first threshold value when the input radiation is high and a second threshold value when the input radiation is low.

23. The method of claim 18, further comprising:
activating, by the electronic device, a response to the indicated user input of the at least one key.

24. The method of claim 23, where the response comprises at least one of playing of a sound, lighting up the at least one key, or the lighting up one or more portions of the display.

25. The method of claim 18, further comprising:
illuminating the at least one key using an illumination device of the electronic device to produce the input radiation.

26. The method of claim 18, where the input radiation comprises ambient light.

27. An electronic device comprising:
at least one key associated with a display of the electronic device;
a solar cell associated with the at least one key, the solar cell having an output signal, where a change of input radiation received at the solar cell corresponds to a change in the output signal, the at least one key to transmit input radiation to the solar cell; and
a cell monitoring unit to detect the change of the output signal corresponding to the change in the transmitted input radiation when the input radiation is prevented from being received at the at least one key, and indicate, based on the detected output signal change, a user input of the at least one key.

28. The electronic device of claim 27, where the cell monitoring unit is further to monitor the output signal of the solar cell to enable the detection of the change of the output signal.

28. The electronic device of claim 28, where the at least one key comprises a plurality of keys, each of the plurality of keys being respectively associated to a particular solar cell, and where the cell monitoring unit is further to separately monitor the output signals of each of the particular solar cells.

30. The electronic device of claim 27, where the cell monitoring unit is further to compare the detected output signal change to a threshold value, and when the threshold value is attained, the cell monitoring unit is to trigger the indication of the user input of the at least one key.

31. The electronic device of claim 30, further comprising:
an input control unit, the input control unit to activate, based on the indicated key input, an input response in the electronic device.

32. The electronic device of claim 27, further comprising:
an illumination unit to illuminate the at least one key with the input radiation when the at least one key is unobstructed.

33. The electronic device of claim 32, where the illumination unit is connected to the cell monitoring unit, and the cell monitoring unit is further to determine when the illumination unit is powered on or powered off.

34. The electronic device of claim 27, where the input radiation comprises ambient light.

35. The electronic device of claim 27, where the solar cell is an infrared solar cell.

36. The electronic device of the claim 27, where the electronic device comprises a wireless device or a radio communication device.

37. The electronic device of claim 27, where the electronic device is powered, using the input radiation, by the solar cell.
